(19) United States
(12) Patent Application Publication
(10) Pub. No.: US 2020/0303156 A1
(43) Pub. Date: Sep. 24, 2020

(54) BEAM SPLITTER FOR A CHARGED PARTICLE DEVICE

(71) Applicant: ICT Integrated Circuit Testing Gesellschaft für Halbleiterprüftechnik mbH, Heimstetten (DE)

(72) Inventors: Dieter Winkler, Munchen (DE); Benjamin John Cook, Munchen (DE)

(21) Appl. No.: 16/359,831

(22) Filed: Mar. 20, 2019

(51) Int. Cl. H01J 37/147; H01J 37/20; H01J 37/09; H01J 37/28

(52) U.S. Cl. CPC H01J 37/1477; H01J 37/20; H01J 2237/0453; H01J 37/28; H01J 2237/202; H01J 37/09

(57) ABSTRACT

A beam splitter for generating a plurality of charged particle beamlets from a charged particle source is disclosed. The beam splitter includes a plurality of beamlet deflectors, which each pass a beamlet along an optical axis. Each beamlet deflector includes a low order element and a corresponding high order element. Each low order element has fewer electrodes than each corresponding high order element; and each low order element is one of a plurality of low order elements; and each corresponding high order element is one of a plurality of high order elements.

### TECHNICAL FIELD

Embodiments described herein relate to charged particle beam devices, such as scanning electron microscopes configured to inspect specimens such as wafers or other substrates, e.g. to detect pattern defects. Embodiments described herein relate to charged particle beam devices configured to utilize multiple charged particle beams, e.g. a plurality of electron beamlets, particularly for inspection system applications, testing system applications, defect review or critical dimensioning applications, surface imaging applications or the like. Embodiments further relate to a beam splitter for generating multiple beamlets.

### BACKGROUND

There is a high demand for structuring and probing specimens in the nanometer or even in the sub-nanometer scale, particularly in the electronics industry. Micrometer and nanometer scale process control, inspection or structuring is often done with charged particle beams, e.g. electron beams, which are generated, shaped, deflected and focused in charged particle beam devices, such as electron microscopes. For inspection purposes, charged particle beams offer high spatial resolution compared to many optical methods, because electron wavelengths can be significantly shorter than the wavelengths of optical beams.

Inspection devices using charged particle beams such as scanning electron microscopes (SEM) have many functions in industrial fields, including, but not limited to, inspection of electronic circuits, exposure systems for lithography, detecting devices, defect inspection tools, and testing systems for integrated circuits. In charged particle beam systems, fine probes with high current density can be used.

It is attractive to use multiple beams (referred to herein as beamlets) in a charged particle device, to, for example, be able to increase throughput of large scale sample inspection, such as of integrated circuits. Generating, directing, scanning, deflecting, shaping, correcting, and/or focusing beamlets can be technically challenging, in particular when sample structures are to be scanned and inspected in a quick manner with high throughput with nanoscale resolution.

### SUMMARY

Disclosed herein is a beam splitter for generating a plurality of charged particle beamlets from a charged particle source. The beam splitter includes a plurality of beamlet deflectors which each pass a beamlet. There is a first deflector for passing a first beamlet and a second deflector for passing a second beamlet. Each beamlet deflector includes a low order element and a corresponding higher-order element. Each lower order element has fewer electrodes than each corresponding higher-order element. Each low order element is one of a plurality of low order elements. Each corresponding higher-order element is one of the plurality of higher-order elements.

Disclosed herein is a charged particle beam device that includes a beam splitter that generates charged particle beamlets from a charged particle source. The beam splitter includes a plurality of beamlet deflectors which each pass a beamlet. There is a first deflector for passing a first beamlet and a second deflector for passing a second beamlet. Each beamlet deflector includes a low order element and a corresponding higher-order element. Each lower order element has fewer electrodes than each corresponding higher-order element. Each low order element is one of a plurality of low order elements. Each corresponding higher-order element is one of the plurality of higher-order elements. The charged particle beam device is configured for sample inspection with the plurality of charged particle beamlet. The device includes a charged particle source, followed by a collimating lens and the beam splitter described above. The device also includes a deflector for deflecting the beamlets generated by the beam splitter, the deflector directing the beamlets through a second beam splitter, and a scanner and an objective lens in that order. The objective lens is configured to focus the beamlets on a sample placed on a movable stage of the charged particle beam device, and collect signal charged particles. The second beam splitter directs the collected signal charged particles to a detector. The charged particle beam device further includes a controller which is communicatively coupled to the scanner, deflector, detector, and beam splitter.

Disclosed herein is a method of generating a plurality of charge particle beamlets. The method includes directing a single beam of charged particles through a beam splitter. The beam splitter includes a plurality of beamlet deflectors which each pass a beamlet. There is a first deflector for passing a first beamlet and a second deflector for passing a second beamlet. Each beamlet deflector includes a low order element and a corresponding higher-order element. Each lower order element has fewer electrodes than each corresponding higher-order element. Each low order element is one of a plurality of low order elements. Each corresponding high order element is one of a plurality of high order elements. A low order electrical field is applied to the charged particles with a low order electrostatic element which deflects the charged particles. High order electrical field is applied to the charged particles with the high order electrostatic element to correct aberrations. Charged particle beamlets are generated as the charged particles pass through apertures aligned with the centers of each beamlet deflector.

### BRIEF DESCRIPTION OF THE DRAWINGS

So that the manner in which the above recited features can be understood in detail, a more particular description, briefly summarized above, may be had by reference to embodiments. The accompanying drawings relate to embodiments and are described in the following:

FIG. 1 illustrates a charged particle beam device according to embodiments described herein;

FIG. 2 illustrates a beam splitter according to embodiments described herein;

FIG. 3 illustrates a beam splitter according to embodiments described herein;

FIG. 4 illustrates a beam splitter according to embodiments described herein;

FIG. 5 illustrates a beam splitter according to embodiments described herein;

FIG. 6 illustrates a low order element and conductive lines, according to embodiments described herein;

FIG. 7 illustrates a low order element and conductive lines, according to embodiments described herein;

FIG. 8 illustrates a high order element and conductive lines, according to embodiments described herein;

FIG. 9 illustrates a method of generating a plurality of charged particle beamlets, according to embodiments described herein.

### DETAILED DESCRIPTION

Herein are used relative terms such as low and high, such as referring to the multipolar order of beam deflecting elements used, for example, to influence the shape and/or trajectory of charged particles, especially in the form of beams or beamlets. The usage of relative terms “high” and “low” is intended to convey comparative meaning, in the sense that a low order element is configured to provide a lower order multipole than a corresponding high order element. This may be manifest in the number of electrodes of the low or high order element.

In an embodiment that may be combined with every embodiment disclosed herein, a low order element has fewer electrodes than a high order element, so that the low order element generates a lower order multipolar field than a high order element. As an example, a low order element could be made of a pair of electrodes that generate a dipole; and a high order element could be made of eight electrodes that generate an octupole. The relative terms high magnitude and low magnitude, likewise, are relative terms which are intended to convey a comparative meaning. For example, a high magnitude low order multipole may have higher magnitude and fewer multipoles than a low magnitude high order multipole.

Herein the term “along the optical axis” is used, such as to convey the beam path of a charged particle beamlet. The usage of “along” in the term is intended to convey that the path is substantially parallel to the optical axis, although some divergence or convergence is possible. Beamlets' respective paths may deviate from being completely parallel from the optical axis of a charged particle device, such as when (or immediately after) the beamlets pass through the beam splitter disclosed herein.

Herein, multipolar beam deflectors are described, with the intended meaning that a dipolar beam deflector generates an electric field which is very well described as a dipolar field, although small perturbations or the like of higher multipoles may exist. Likewise, a quadrupole can generate an electric field that is very well described by no more than a quadrupolar field, although small perturbations or the like of higher multipoles may exist. Extending the concept further, an octupole generates a field that is very well described by no more than an octupolar field; and so on.

Herein, the terms sample and specimen are used interchangeably. Herein, the attachment of one substrate with another may be through the use of an adhesive such as a silicon based adhesive. Attaching substrates together, as described herein, may include steps of aligning respective structures on the substrates, particularly apertures, electrodes, and/or elements of beamlet deflectors.

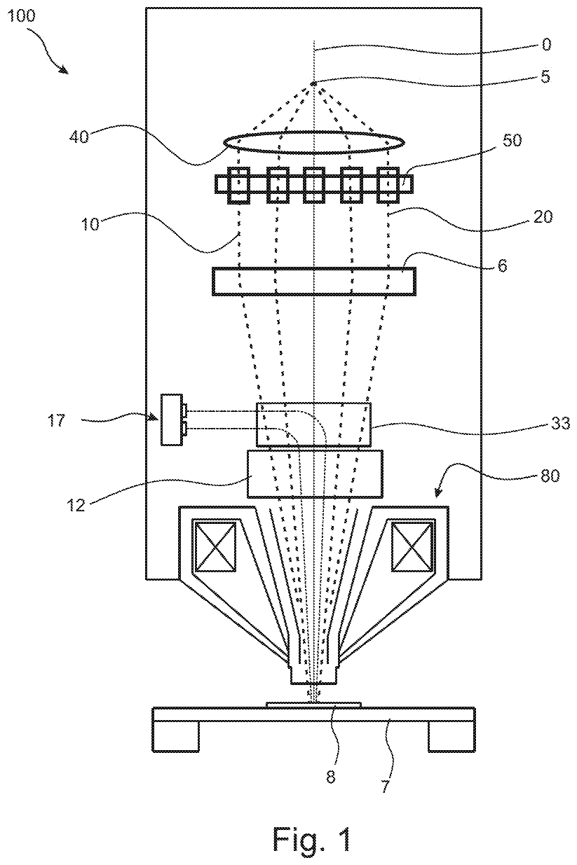

FIG. 1 illustrates a charged particle beam device, according to embodiments described herein. The charged particle beam device 100 may be a scanning electron microscope. The charged particle beam device 100 includes a charged particle source 5. A collimating lens 40 can direct the beam of the charged particles toward a beam splitter 50. Alternatively, the collimating lens 40 can be positioned on the other side of the beam splitter 50 from the source. The beam splitter 50 passes a plurality of beamlets. In FIG. 1, the first beamlet 10 and the second beamlet 20 are labeled. There can be more than two beamlets. The beamlets can propagate along an optical axis 0. The beamlets can be arranged in an array.

A plurality of beamlets arranged along a ring which is centered on the optical axis is particularly contemplated. It can be advantageous, yet present technical hurdles, to form multiple beamlets from a single charged particle source 5. For example, a charged particle beam device 100 which uses a single column and a single charged particle source can be made more compact than using multiple columns and multiple sources.

The charged particle source 5 may be an electron source configured to generate an electron beam. Alternatively, the beam source may be an ion source configured to generate an ion beam. In some embodiments, the beam source 105 may include at least one of a cold field emitter (CFE), a Schottky emitter, a thermal field emitter (TFE) or another high current electron beam source, in order to increase the throughput. A high current is considered to be 10 μA in 100 mrad or more, for example up to 5 mA, e.g. 30 μA in 100 mrad to 1 mA in 100 mrad. According to typical implementations, the current is distributed essentially uniformly, e.g. with a deviation of ±10%. According to some embodiments, which can be combined with other embodiments described herein, the beam source can have an emission half angle of about 5 mrad or above, e.g. 50 mrad to 200 mrad. In some embodiments, the beam source may have a virtual source size of 2 nm or more and/or 40 nm or less. For example, if the beam source is a Schottky emitter, the source may have a virtual source size from 10 nm to 40 nm. For example, if the beam source is a cold field emitter (CFE), the source may have a virtual source size from 2 nm to 20 nm.

According to embodiments, which can be combined with other embodiments described herein, a TFE or another high reduced-brightness source capable of providing a large beam current is a source where the brightness does not fall by more than 20% of the maximum value when the emission angle is increased to provide a maximum of 10 μA-100 μA.

The beamlets 10, 20 may propagate toward a sample 8 through a column along the optical axis 0. The beamlets may be operated upon by elements such as one or more deflectors, beam correctors, lens devices, apertures, beam benders and/or beam separators. FIG. 1 shows a deflector 6 which can be used to deflect the beam path of each beamlet 10, 20. The deflector 6 can alter the paths of each beamlet to make it appear that each beamlet 10, 20 originates from a different source. A scanner 12 can scan each beamlet 10, 20 while irradiating the sample 8, such as during imaging and/or signal acquisition. The beamlets 10, 20 can be focused by an objective lens 80 onto the sample 8. Each beamlet 10, 20 can be focused on a different spot such as forming an array. The sample 8 can be movable, such as by the movement of a stage 7, e.g. a translatable stage. It is advantageous to be able to have a large number of beamlets, particularly the ability to have many high intensity beamlets.

The objective lens system 109 may include a combined magnetic-electrostatic objective lens including a magnetic lens portion and an electrostatic lens portion. In some embodiments, a retarding field device may be provided which is configured to reduce the landing energy of the charged particles on the specimen. For example, a retarding field electrode may be arranged upstream of the specimen. The objective lens 80 can also collect signal charge particles and direct them to a second beam splitter 33. The second beam splitter 33 may direct signal charge particles toward a detector 17. Signal charge particles may be secondary electrons and/or backscattered electrons.

A controller can be communicatively coupled to the components, such as the beam splitter 50, detector 17, the stage 7, and the scanner 12. The controller can provide power to lens elements and the like, such as the electrodes of electrostatic lenses.

The detector 17 can include detector elements which can be configured for generation of a measurement signal, e.g. an electronic signal corresponding to detected signal electrons. The controller can receive data generated by the device, such as by the detector.

There are many technical challenges associated with the generation and control of multiple beamlets. Herein is described a beam splitter 50 which can be used to generate multiple beamlets from a charged particle source and/or a single charged particle beam. A beam splitter 50, particularly those described herein, can be made from a monolithic piece, such as from a single piece of silicon or SOI wafer (silicon on insulator). To form the beam splitter 50, various structures such as electrodes, conductive lines, through-holes, etc. can be formed on and/or in a substrate, e.g. a monolith, silicon water, or SOI wafer.

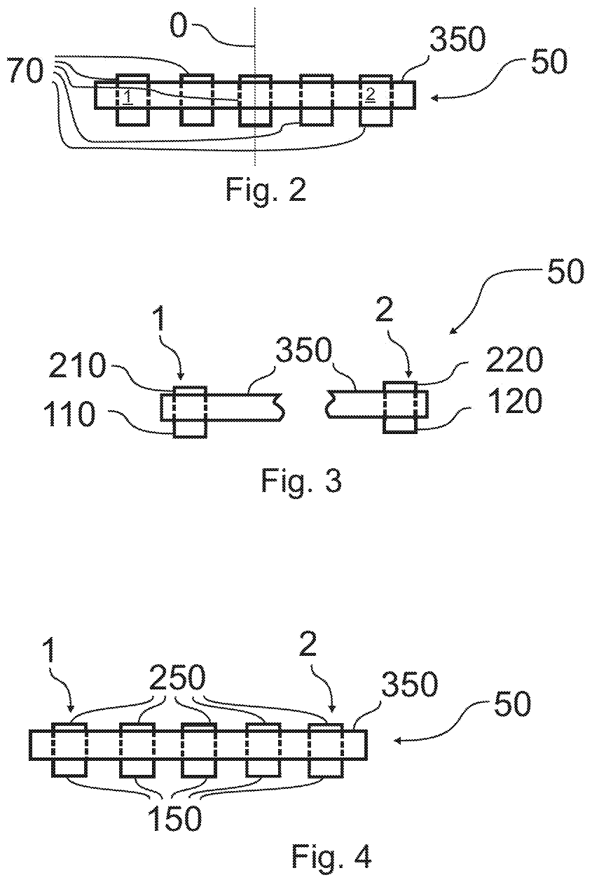

FIG. 2 shows a beam splitter 50, according to embodiments described herein. The beam splitter 50 includes a plurality of beamlet deflectors 70. Each beamlet deflector passes a beamlet. The beamlet deflectors can be arranged on a substrate or more than one substrate. A single piece of silicon, and/or another off-the-shelf construction such as silicon with an in-built insulation layer, e.g. a SOI wafer (e.g. silicon and silicon oxide), can be a substrate. An SOI can be a wafer with around a 100 μm layer of Si followed by a 2 μm layer of insulating oxide and then a >100 μm layer of silicon. The beam splitter 50 may have all the beamlet deflectors 70 on the same substrate.

The beam splitter 50 has an optical axis 0 which can be substantially perpendicular to the plane of the beam splitter 50, particularly the at least one substrate 350. FIG. 2 shows a first deflector 1, and a second deflector 2; there can be more than two deflectors.

FIG. 3 shows a beam splitter 50, according to embodiments described herein. The first and second deflectors 1, 2 of the plurality of beamlet deflectors 70 (see FIG. 2) are shown in FIG. 3. Each deflector 1, 2 includes a low order element 110, 120 and a high order element 210, 220. In other words, the first deflector 1 includes a first low order element 110 and a first high order element 210; the second deflector 2 includes a second low order element 120 and a second high order element 220. The first deflector 1 includes a first low order element 110 which is aligned with a first high order element 210; the second deflector 2 includes a second low order element 120 which is aligned with a second high order element 220.

In FIGS. 3 and 4, the plurality of low order elements 150 are shown to be on the opposite surface of a substrate 350 as the plurality of high order elements 250. Alternatively, the low and high order elements can be on different substrates that are attached together. The substrates may be attached together such that the low and high order elements are in alignment parallel to the optical axis 0. Alternatively, the low and high order elements may be on the opposite sides of the same substrate.

The low order elements can be high voltage elements and the high order elements can be low voltage elements. The low order elements can be configured for applying a large deflection to the beamlets, by, for example, applying of a strong (e.g. relatively high magnitude) low order multipole. The high order can be configured for applying an aberration correction, by, for example, applying a weak (e.g. a relatively low magnitude) high order multipole.

For example, each low order element can be a dipole element. Each high order element is configured to generate a higher multipole than the corresponding low order element. For example, the high order elements each generate an octupole, e.g. an electrostatic octupole, to respective beamlets, and the low order element generates a lower order multipolar field, such as a dipole or quadrupole.

FIG. 4 illustrates a beam splitter 50 according to embodiments described herein. In FIG. 4, the plurality of low order elements 150 and the plurality of high order elements 250 are labeled. For example, the first deflector 1 includes one of the plurality of low order elements 150 and a corresponding one the plurality of high order elements 250. As depicted in FIG. 4, the plurality of low order elements and the plurality of corresponding high order elements may be on opposite sides of the same substrate 350. Alternatively, the plurality of low order elements and the plurality of corresponding high order elements may be on different substrates which can be attached together.

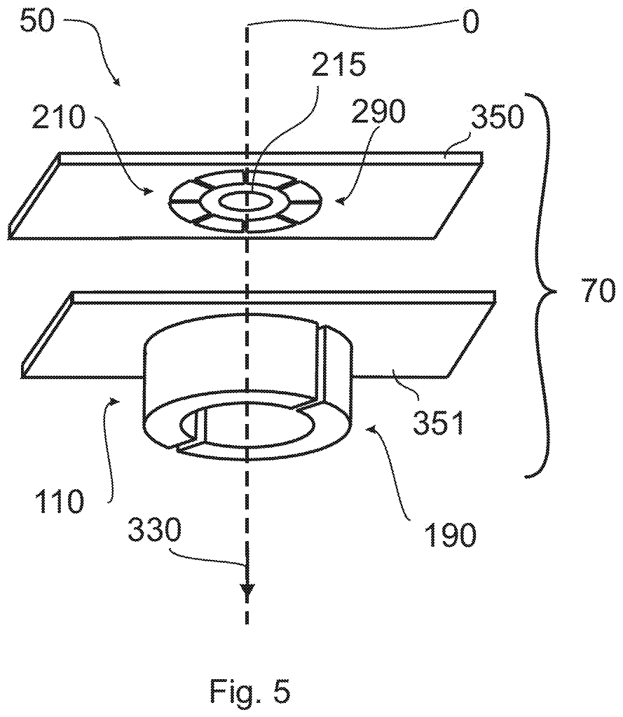

FIG. 5 shows a beam splitter 50 according to embodiments described herein. The plurality of low order elements 150 may each be on a substrate 350, and the plurality of corresponding high order elements 250 may each be on a corresponding substrate 351, such as another substrate. The substrates may be connected together, such as fastened together.

The beamlet deflector 70 can have a surface for facing the charged particle source which can be coated with a conductive material, such as a metal film, to reduce charging effects. The substrate 350 which has the surface for facing the charged particle source may have the low order elements 150 or the high order elements 250 on the opposite surface.

As seen in FIG. 5, a low order element 110 and corresponding high order element 210 are oriented in parallel with the optical axis 0 (one of each low and high order elements 110, 120 may be aligned directly with the optical axis). The propagation direction 330 of each beamlet is approximately along (i.e. approximately parallel to) the optical axis 0. Each low order element and its corresponding high order element, and their respective apertures, may be oriented in parallel with the optical axis 0 so as to each pass a beamlet therethrough. The substrate 350 can have a plurality of apertures aligned with the centers of each beamlet deflector 70. In FIG. 5, the high order element 210 is shown to have an aperture 215, which can be aligned with a corresponding aperture (not visible in FIG. 5) of the low order element 1210. When the high and low order elements 110, 120 share a substrate (e.g. the elements 110, 120 are on opposite sides of the same substrate), each low order element and its corresponding high order element can share an aperture as well.

Each low order element, including the first low order element 110 depicted in FIG. 5, can have fewer electrodes than the corresponding high order element 210. Each low order element 150 can be an electrostatic element, and each high order element 250 can be an electrostatic element. The low order elements 150 can be configured to apply a large deflection to the beamlets (such as by application of a high magnitude low order multipole); and the high order elements 250 can be configured to correct aberrations (such as by application of a low magnitude high order multipole). Each low order element can be a high voltage element and each corresponding high order element can be a low voltage element.

The footprint of each beamlet deflector 70 in the plane perpendicular to the optical axis can be less than 4 mm², 3 mm², 2.25 mm², 2 mm², 1 mm², 900 μm², 800 μm², or 700 μm², or approximately 625 μm². A small footprint can be desirable for allowing for a high density of beamlet deflectors 70 from the same beam splitter 50. The footprint of each beamlet deflector 70 can be from 25 μm×25 μm to 2 mm×2 mm; or from 30 μm×30 μm to 1.5 mm×1.5 mm. A high density of beamlet deflectors 70 can result in a high density of beamlets, which can be desirable, for example, for efficiently using the source energy for a large number of high current charged particle beamlets. It can also be desirable to have discrete, well-separated beamlets with little interaction between neighboring beamlets. It can be technically challenging to produce high spatial density beamlets which are nonetheless well separated in the sense of having manageable (e.g. negligible) beamlet-beamlet interactions. The footprint of an electrode of a beamlet deflector 70 can be less than 10 μm², 8 μm², 5 μm², 4 μm², or 2 μm².

As shown in FIG. 5, the low order elements 150 can be longer than the high order elements 250 along the optical axis 0. The relatively large extent of the low order elements 150, including the first low order element 110, in the direction of the optical axis (particularly in comparison to the high order element 250) can make it possible to generate greater deflection to each beamlet 10, 20. It is possible to use high voltage with the low order elements 150, such as when the low order electrodes 190 of each low order element 110, 120 have a large length in the direction of the optical axis 0, such as, to yet further increase the magnitude of beamlet deflection.

It is particularly contemplated to have an embodiment in which, along the optical axis, the length of the low order elements is from about 10 μm up to about 2 mm; and the length of the high order elements is less than 200 μm.

In an embodiment that can be combined with any other embodiment, a center-center spacing between the beamlet deflectors 70 in a direction perpendicular to the optical axis can be less than 5 mm, 2 mm, 1 mm, 0.5 mm, or 0.25 mm.

As disclosed herein, it is possible to maintain a small footprint of each beamlet deflector 1, 2 by separating the functions of the beam splitter 50, which generates the plurality of beamlet 10, 20 from a charged particle source 5, into a low order component largely responsible for deflection of the beamlets, and a high order component largely for aberration correction of the beamlets. As disclosed herein, a plurality of low order elements can be high voltage elements for deflection, and a plurality of corresponding high order elements can be low voltage elements for aberration correction.

There can optionally be a plurality of third deflecting elements, such as for fine adjustment, aberration correction, and/or astigmatism correction. A respective third deflecting element, to add to each low order element 150 and corresponding high order element 250, can be a quadrupole, decapole, or tetradecapole, for example. Such a plurality of third deflector elements is particularly envisioned in combination with dipolar low order elements; furthermore, in such an embodiment, the high order elements can each be octupoles. Each third deflecting element can also have an aperture in alignment with the respective apertures of the low and high order elements. A plurality of third deflecting elements may be positioned on another substrate, which can be attached to, such as fixed in alignment with, the substrate(s) of the low and high order elements.

FIG. 6 shows a low order element 110, 120 according to embodiments described herein. The low order element 110 can be on a surface of a substrate. The low order element 110 has at least two low order electrodes 190 for applying at least a dipolar field to a beamlet which can pass through an aperture 115. The low order electrodes 190 can face each other with the aperture 115 between. In an embodiment, each low order element 110, 120 is a dipole element, and one of the electrodes of each low order element is ground.

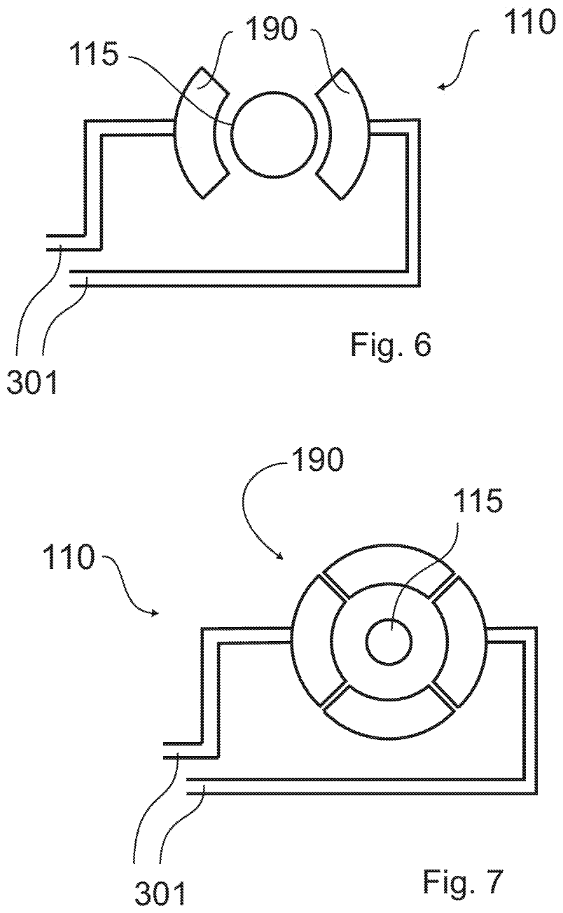

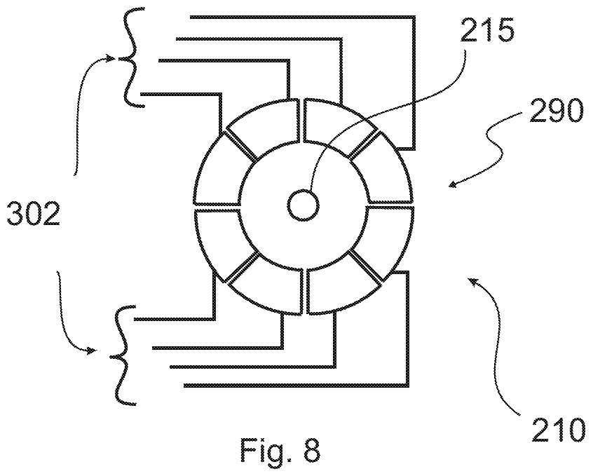

The low order element 110 can be for generating a dipolar field, e.g. for generating a substantially dipolar electric field, with comparatively small, e.g. negligible, higher order field components in comparison to the dipolar field. The low order electrodes 190 can each have the shape of a ring segment. The smaller arc of the ring segment can be adjacent to the aperture, as depicted in FIG. 6. As depicted in FIGS. 6 and 7, the low order electrodes 190 can be approximately 90° ring segments. The low order electrodes 190 and/or high order electrodes 290 can be shaped and/or arranged so as to minimize higher order aberrations. The electrodes may generally each be shaped like a segment of a ring. In a dual electrode arrangement analogous to that shown in FIG. 6, electrodes which are approximately 120° ring segments are possible.

FIG. 6 also shows high voltage conductive lines 301 that connect to each low order electrode 190 of a low order element, according to embodiments described herein. A plurality of high voltage conductive lines 301 can connect respectively to each low order element 110, 120.

FIG. 7 shows a low order element 110, 120 according to embodiments described herein. The low order element 110 can have four low order electrodes 190 for applying at least a dipolar field to a beamlet which can pass through an aperture 115. The low order electrodes 190 can surround an aperture 115 through which a beamlet may pass. The low order element 110 can be for generating a dipole, e.g. for generating a nearly exclusively dipolar electric field.

In an embodiment, each low order element 110, 120 has four electrodes 190, including two ground electrodes facing each other with the aperture between. Conductive lines connecting ground electrodes to ground may be present (not shown in FIG. 7).

FIG. 8 illustrates a high order element 210 according to embodiments described herein. The high order element 210 can have multiple high order electrodes 290 for applying a multipolar field to a beamlet which can pass through an aperture 215. The high order electrodes 290 can surround an aperture 215 through which a beamlet may pass. The high order element 210 can be for generating a quadrupole, octupole (as depicted), or higher N-pole.

FIG. 8 also shows low voltage conductive lines 302 that connect to each high order electrode 290 of the high order element 210, according to embodiments described herein. A plurality of low voltage conductive lines 302 can connect respectively to each high order element 210, 220.

FIGS. 6-8 each show conductive lines, which may be present on the surface of the respective substrates.

A controller may connect to the low and high voltage conductive lines.

In an embodiment that can be combined with any other embodiment described herein, the cross section of each high voltage conductive line 301 is greater than that of each low voltage conductive line 302. The relatively low cross-section of the low voltage conductive lines 302 can allow a higher density of conductive lines on the substrate surface. A higher density of conductive lines can make it possible to address and/or control more electrodes. A higher density of conductive lines can allow for higher order multipoles for the low order elements, which can be used mainly for aberration correction, and/or it can provide for a higher density of the high order elements themselves, meaning a greater areal density of charged particle beamlets.

By separating the function of the beam splitter 50 into i) low order deflection (with low order elements 150), which may require relatively high voltages which can limit the areal number density of high voltage conductive lines 301, and ii) high order aberration correction (with high order elements 250), which can exploit a higher areal number density of low voltage conductive lines 302 because of the possibility of using lower voltages, it is possible to increase the areal number density of generated charged particle beamlets. In other words, the spacing between neighboring beamlet deflectors 70 can be decreased.

As seen in FIGS. 6, 7, and 8, the respective apertures of each low and high order element can be centered within the respective plurality of electrodes of each element. It is also to be appreciated that the spacing between adjacent low order electrodes 190 may be greater than the spacing between adjacent high order electrodes 290.

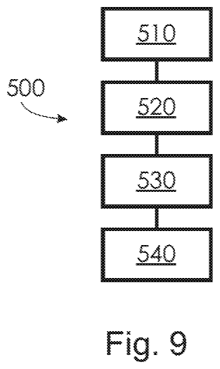

In FIG. 9, a method generating a plurality of charged particle beamlets is shown, according to embodiments described herein. The method 500 can include directing a single beam of charged particles to a beam splitter 510. A low order electrical field can be applied to the charged particles with the low order elements, to deflect the charged particles 520. A high order electrical field can be applied to the charged particles with the high order element to correct aberrations 530. A plurality of charged particle beamlets can be generated as the charged particles pass through a plurality of apertures aligned with the centers of each beamlet deflector 540.

This disclosure is intended to include the following enumerated embodiments, in which references to reference numerals and/or figures are mentioned to aid in understanding, without the intent of the reference numerals or figures to be limiting:
1. A beam splitter (50) for generating a plurality of charged particle beamlets (10,20) from a charged particle source (5), comprising:
   a plurality of beamlet deflectors (70), which each pass a beamlet (10, 20) along an optical axis, including a first deflector (1) for passing a first beamlet (10) and a second deflector (2) for passing a second beamlet (20); wherein
   each beamlet deflector (1, 2) includes a low order element (150; 110, 120) and a corresponding high order element (250; 210, 220); wherein each low order element has fewer electrodes than each corresponding high order element; and each low order element (150) is one of a plurality of low order elements; and each corresponding high order element (210, 220) is one of a plurality of high order elements.
2. The beam splitter of embodiment 1, wherein each low order element is a high voltage element and each corresponding high order element is a low voltage element.
3. The beam splitter of any preceding enumerated embodiment, wherein the plurality of low order elements is arranged on a substrate (350), the substrate having a plurality of apertures, in a plane perpendicular to the optical axis, aligned with the centers of each beamlet deflector; and the plurality of high order elements are arranged on a corresponding substrate or the opposite side of the substrate (in a plane); wherein the beam splitter is optionally formed from a single substrate such as silicon or SOI (e.g. each low order/high order pair of elements can share an aperture).
4. The beam splitter of any preceding enumerated embodiment, wherein each low order element has an aperture aligned to a corresponding aperture of each corresponding high order element, (the apertures and corresponding apertures extending along the optical axis).
5. The beam splitter of any preceding enumerated embodiment, wherein each low order element (150) and each high order element is an electrostatic element.
6. The beam splitter of any preceding enumerated embodiment, wherein the first deflector (1) includes a first low order element aligned with a first high order deflector element; and
   the second deflector (2) includes a second low order element aligned with a second high order element.
7. The beam splitter of any preceding enumerated embodiment, wherein each low order element is configured to apply a large deflection to each respective beamlet (by application of a strong low order multipole); and each high order element is configured to correct aberrations of each respective beamlet (by application of a weak high order multipole).
8. The beam splitter of any preceding enumerated embodiment, wherein
   each low order element is a dipole element; and
   each high order element is configured to generate a multipole greater than a dipole, (e.g. octupole or higher).
9. The beam splitter of any preceding enumerated embodiment, further comprising
   a plurality of high voltage conductive lines (302) connected respectively to each low order element; and
   a plurality of low voltage conductive lines (301) connected respectively to each high order element.
10. The beam splitter of enumerated embodiment 9, wherein
   the high voltage conductive lines have a larger cross section than the low voltage conductive lines.
11. The beam splitter of enumerated embodiment 10, wherein
   a footprint of each beamlet deflector (70) in a plane perpendicular to the optical axis is less than 4 mm².
12. The beam splitter of any preceding enumerated embodiment, wherein
   each low order element (150) is longer than each corresponding high order element (250) along the optical axis.
13. The beam splitter any preceding enumerated embodiment, wherein
   along the optical axis, the length of each low order element is more than 100 μm, and
   the length of each corresponding high order element is less than 200 μm.
14. The beam splitter of any preceding enumerated embodiment, wherein
   a center-center spacing between the beamlet deflectors in a direction perpendicular to the optical axis is less than 2 mm (down to 0.25 mm for example).
15. The beam splitter of any preceding enumerated embodiment, wherein
   each low order element is a dipole element, and one of the electrodes of each low order element is ground, the electrodes facing each other with the aperture between; or
   the low order element has four electrodes, including two ground electrodes facing each other with an aperture between.
16. The beam splitter of any preceding enumerated embodiment, wherein
   each low order electrode is one of a pair of dipole electrodes and is shaped for minimizing higher order aberrations.
17. The beam splitter of any preceding enumerated embodiment, further comprising
a metal film coated on a side of the beam splitter for facing the charged particle source.
18. The beam splitter of any preceding enumerated embodiment, wherein each beamlet deflector (70) further comprises
   a plurality of third deflecting elements (such as a quadrupole [e.g. fine adjustment, astigmatism correction] or decapole or tetradecapole); wherein each high order element is an octupole.
19. The beam splitter of any preceding enumerated embodiment, wherein the beam splitter is formed from a single substrate, such as silicon or SOI, and each low order element and each corresponding high order element share a corresponding aperture through the substrate.
20. A charged particle beam device for sample inspection with a plurality of charged particle beamlets, comprising:
   a charged particle source, followed by
   a collimating lens and a beam splitter according to enumerated embodiment 1,
   a deflector for deflecting the beamlets generated by the beam splitter, the deflector directing the beamlets through a second beam splitter, and a scanner and an objective lens in that order, wherein the objective lens is configured to
      focus the beamlets on a sample placed on a movable stage of the charged particle beam device, and
      collect signal charged particles, and
   the second beamsplitter directs the collected signal charged particles to a detector; the charged particle beam device further including
   a controller which is communicatively coupled to the scanner, deflector, detector, and beam splitter. 21. A method of generating a plurality of charged particle beamlets, comprising:
directing a single beam of charged particles to a beam splitter according to enumerated embodiment 1,
applying a low order electrical field to the charged particles with the low order element to deflect the charged particles,
applying a high order electrical field to the charged particles with the high order element to correct aberrations, and
generating a plurality of charged particle beamlets as the charged particles pass through a plurality of apertures aligned with the centers of each beamlet deflector.

Various embodiments of the present invention have been described above. It should be understood that they have been presented by way of illustration and example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the appended claims and their equivalents. It will also be understood that each feature of each embodiment discussed herein can be used in combination with the features of any other embodiment. Furthermore, there is no intention to be bound by any expressed or implied theory presented in the preceding technical field, background, brief summary or the detailed description.

1. A beam splitter for generating a plurality of charged particle beamlets from a charged particle source, comprising:
a plurality of beamlet deflectors, which each pass a beamlet along an optical axis, including a first deflector for passing a first beamlet and a second deflector for passing a second beamlet; wherein
each beamlet deflector includes a low order element and a corresponding high order element; wherein
each low order element has fewer electrodes than each corresponding high order element; and each low order element is one of a plurality of low order elements; and each corresponding high order element is one of a plurality of high order elements.

2. The beam splitter of claim 1, wherein
each low order element is a high voltage element and each corresponding high order element is a low voltage element.

3. The beam splitter of claim 1, wherein
the plurality of low order elements is arranged on a substrate, the substrate having a plurality of apertures, in a plane perpendicular to the optical axis, aligned with the centers of each beamlet deflector; and
the plurality of high order elements are arranged on a corresponding substrate or the opposite side of the substrate.

4. The beam splitter of claim 1, wherein
each low order element has an aperture aligned to a corresponding aperture of each corresponding high order element.

5. The beam splitter of claim 1, wherein
each low order element and each high order element is an electrostatic element.

6. The beam splitter of claim 1, wherein
the first deflector includes a first low order element aligned with a first high order deflector element; and
the second deflector includes a second low order element aligned with a second high order element.

7. The beam splitter of claim 1, wherein
each low order element is configured to apply a large deflection to each respective beamlet; and
each high order element is configured to correct aberrations of each respective beamlet.

8. The beam splitter of claim 1, wherein
each low order element is a dipole element; and
each high order element is configured to generate a multipole greater than a dipole.

9. The beam splitter of claim 1, further comprising
a plurality of high voltage conductive lines connected respectively to each low order element; and
a plurality of low voltage conductive lines connected respectively to each high order element.

10. The beam splitter of claim 9, wherein
the high voltage conductive lines have a larger cross section than the low voltage conductive lines.

11. The beam splitter of claim 10, wherein
a footprint of each beamlet deflector in a plane perpendicular to the optical axis is less than 4 mm².

12. The beam splitter of claim 1, wherein
each low order element is longer than each corresponding high order element along the optical axis.

13. The beam splitter of claim 1, wherein
along the optical axis, the length of each low order element is more than 100 μm, and
the length of each corresponding high order element is less than 200 μm.

14. The beam splitter of claim 1, wherein
a center-center spacing between the beamlet deflectors in a direction perpendicular to the optical axis is less than 2 mm.

15. The beam splitter of claim 1, wherein
each low order element is a dipole element, and one of the electrodes of each low order element is ground, the electrodes facing each other with the aperture between; or
the low order element has four electrodes, including two ground electrodes facing each other with an aperture between.

16. The beam splitter of claim 1, wherein
each low order electrode is one of a pair of dipole electrodes and is shaped for minimizing higher order aberrations.

17. The beam splitter of claim 1, further comprising
a metal film coated on a side of the beam splitter for facing the charged particle source.

18. The beam splitter of claim 1, wherein
each beamlet deflector further comprises
a plurality of third deflecting elements; wherein
each high order element is an octupole.

19. The beam splitter of claim 3, wherein
the beam splitter is formed from a single substrate of silicon or SOI and each low order element and each corresponding high order element share a corresponding aperture through the substrate.

20. A charged particle beam device for sample inspection with a plurality of charged particle beamlets, comprising:
a charged particle source, followed by
a collimating lens and a beam splitter according to claim 1,
a deflector for deflecting the beamlets generated by the beam splitter, the deflector directing the beamlets through a second beam splitter, and a scanner and an objective lens in that order, wherein
the objective lens is configured to
focus the beamlets on a sample placed on a movable stage of the charged particle beam device, and
collect signal charged particles, and
the second beamsplitter directs the collected signal charged particles to a detector; the charged particle beam device further including
a controller which is communicatively coupled to the scanner, deflector, detector, and beam splitter.

21. A method of generating a plurality of charged particle beamlets, comprising:
directing a single beam of charged particles to a beam splitter according to claim 1,
applying a low order electrical field to the charged particles with the low order element to deflect the charged particles,
applying a high order electrical field to the charged particles with the high order element to correct aberrations, and
generating a plurality of charged particle beamlets as the charged particles pass through a plurality of apertures aligned with the centers of each beamlet deflector.
